(19) United States
(12) Patent Application Publication
(10) Pub. No.: US 2022/0199394 A1
(43) Pub. Date: Jun. 23, 2022

(54) CLEANING METHOD OF SEMICONDUCTOR STRUCTURE

(71) Applicants: Semiconductor Manufacturing International (Shanghai) Corporation, Shanghai (CN); Semiconductor Manufacturing International (Beijing) Corporation, Beijing (CN)

(72) Inventor: Jing ZHANG, Shanghai (CN)

(21) Appl. No.: 17/645,302

(22) Filed: Dec. 20, 2021

(30) Foreign Application Priority Data
Dec. 21, 2020 (CN) 202011523366.9

(51) Int. Cl. H01L 21/02; C01C 1/02

(52) U.S. Cl. CPC H01L 21/02052; C01C 1/024

(57) ABSTRACT

A cleaning method of a semiconductor structure is provided. The method includes providing a substrate, where the substrate includes a functional surface and a back surface that is opposite to the functional surface. The method also includes forming a fluid passivation film on the functional surface of the substrate. In addition, the method includes after forming the fluid passivation film, performing a first charge removal treatment on the functional surface of the substrate through a wet cleaning process. Further, the method includes after performing the first charge removal treatment, performing a main cleaning treatment on the functional surface and the back surface of the substrate.

### CROSS-REFERENCES TO RELATED APPLICATIONS

This application claims the priority of Chinese patent application No. 202011523366.9, filed on Dec. 21, 2020, the entirety of which is incorporated herein by reference.

### FIELD OF THE DISCLOSURE

The present disclosure generally relates to the field of semiconductor manufacturing technology and, more particularly, relates to a cleaning method of a semiconductor structure.

### BACKGROUND

During the manufacturing process of a semiconductor chip, fine foreign matter, metal impurities, and organic impurities may be attached to the semiconductor chip. These impurities may become a cause of malfunction once being attached to the semiconductor wafer. Therefore, the cleanliness of the semiconductor chip is controlled by strict specifications, to prevent these impurities from adhering to the semiconductor chip. Moreover, with the miniaturization and higher performance of semiconductor devices, the management requirements for foreign matter, metal impurities, and organic impurities have become substantially strict. These impurities are often capable of being removed by a wet cleaning method. Thus, the cleaning technology of the semiconductor chip has become a substantially important process in the semiconductor process.

Forming semiconductor chips includes multiple plasma-containing etching processes and ion-implantation processes. The plasma-containing etching process and the ion-implantation process are likely to generate a large amount of charges on the chip surface. In the subsequent wet cleaning process, the charges tend to be released rapidly, which causes serious arc defects and causes great damage to the structure of the chip surface.

Therefore, how to remove the charges on the chip surface is an urgent technical problem that needs to be solved. The disclosed cleaning method is directed to solve one or more problems set forth above and other problems.

### BRIEF SUMMARY OF THE DISCLOSURE

One aspect of the present disclosure includes a cleaning method of a semiconductor structure. The method includes providing a substrate, where the substrate includes a functional surface and a back surface that is opposite to the functional surface. The method also includes forming a fluid passivation film on the functional surface of the substrate. In addition, the method includes after forming the fluid passivation film, performing a first charge removal treatment on the functional surface of the substrate through a wet cleaning process. Further, the method includes after performing the first charge removal treatment, performing a main cleaning treatment on the functional surface and the back surface of the substrate.

Optionally, the fluid passivation film is made of a material including liquid, where the liquid includes pure water or isopropanol.

Optionally, forming the fluid passivation film includes a spray process. Process parameters of the spray process include: a rotation speed in a range of approximately 0-1200 rpm, a flow rate in a range of approximately 0-2000 sccm, and a time period in a range of approximately 0-5 minutes.

Optionally, the wet cleaning process includes a first stage, and a second stage after the first stage. In the first stage, a liquid film of a solution of the wet cleaning process covers a surface of the fluid passivation film, and in the second stage, the liquid film of the solution of the wet cleaning process and the fluid passivation film are inter-soluble, to form a mixed solution film. The mixed solution film is located on the functional surface of the substrate.

Optionally, a ratio of a thickness of the fluid passivation film over a thickness of the liquid film is in a range of approximately 0-5:1.

Optionally, the thickness of the fluid passivation film is in a range of approximately 0-5 mm.

Optionally, the thickness of the liquid film is in a range of approximately 0-5 mm.

Optionally, the solution of the wet cleaning process includes a deionized aqueous solution containing carbon dioxide dissolved therein. Parameters of the wet cleaning process include: a PH value of the solution in a range of approximately 4-7, an electrical conductivity of the solution in a range of approximately 0-50 0/cm, a flow rate of the solution in a range of approximately 0-2000 sccm, a time period in a range of approximately 0-5 minutes, and a rotation speed in a range of approximately 0-1200 rpm.

Optionally, the mixed solution film includes a deionized aqueous solution containing carbon dioxide dissolved therein. A solution of the mixed solution film has a PH value in a range of approximately 4-7, and an electrical conductivity in a range of approximately 0-40 μS/cm.

Optionally, the solution of the wet cleaning process includes a deionized aqueous solution containing ammonia dissolved therein. Parameters of the wet cleaning process include: a PH value of the solution in a range of approximately 7-11, an electrical conductivity of the solution in a range of approximately 0-50 μS/cm, a flow rate of the solution in a range of approximately 0-2000 sccm, a time period in a range of approximately 0-5 minutes, and a rotation speed in a range of approximately 0-1200 rpm.

Optionally, the mixed solution film includes a deionized aqueous solution containing ammonia dissolved therein. A solution of the mixed solution film has a PH value in a range of approximately 7-11, and an electrical conductivity in a range of approximately 0-40 μS/cm.

Optionally, a solution of the main cleaning treatment performed on the functional surface and the back surface of the substrate includes an acidic solution or an alkaline solution.

Optionally, the substrate includes a base and a fin structure over the base, where a surface of the fin structure is the functional surface of the substrate.

Optionally, the substrate includes a base, and a device layer over the base. A surface of the device layer is the functional surface of the substrate. The device layer includes an isolation structure and a device structure located in the isolation structure. The device structure includes at least one of a transistor, a diode, a triode, a capacitor, an inductor, and a conductive structure.

Optionally, the substrate further includes a dielectric layer located over the device layer, and a conductive layer located in the dielectric layer. The conductive layer is electrically connected to the device structure, and a surface of the conductive layer is the functional surface of the substrate.

Optionally, before forming the fluid passivation film on the functional surface of the substrate, the method further includes performing a second charge removal treatment on the back surface of the substrate.

Optionally, the second charge removal treatment performed on the back surface of the substrate includes a wet cleaning process. A solution of the wet cleaning process includes a deionized aqueous solution containing carbon dioxide dissolved therein or a deionized aqueous solution containing ammonia dissolved therein.

The disclosed embodiments may have following beneficial effects. In the disclosed cleaning method of the semiconductor structure, the fluid passivation film may be first formed on the substrate before performing the first charge removal treatment on the substrate surface. On the one hand, when subsequently performing the first charge removal treatment on the substrate surface, in an initial state, the liquid passivation film, the substrate, and the liquid film of the solution of the first charge removal treatment may form the capacitor structure. Therefore, the liquid film of the solution of the first charge removal treatment may not be in direct contact and may not react with the charges on the substrate surface, to avoid generating discharge. On the other hand, as time goes by, the fluid passivation film and the liquid film of the solution of the first charge removal treatment may be inter-soluble, such that the fluid passivation film may dilute the concentration of the liquid film of the solution of the wet cleaning process. Therefore, the electrical conductivity of the formed mixed solution may be reduced, which may effectively prevent the rapid release of the charges on the substrate surface, and may make the release of charges be substantially slow and safe, such that the arc defects may be less likely to occur.

Other aspects of the present disclosure can be understood by those skilled in the art in light of the description, the claims, and the drawings of the present disclosure.

### BRIEF DESCRIPTION OF THE DRAWINGS

FIGS. 1-6 illustrate schematic diagrams of processes corresponding to certain stages of an exemplary cleaning method of a semiconductor structure consistent with various disclosed embodiments of the present disclosure; and

FIG. 7 illustrates a schematic flowchart of an exemplary cleaning method of a semiconductor structure consistent with various disclosed embodiments of the present disclosure.

### DETAILED DESCRIPTION

Reference will now be made in detail to exemplary embodiments of the disclosure, which are illustrated in the accompanying drawings. Wherever possible, the same reference numbers will be used throughout the drawings to refer to the same or the alike parts.

Forming a semiconductor chip includes multiple plasma-containing etching processes and ion-implantation processes. The plasma-containing etching process and the ion-implantation process are likely to generate a large amount of charges on the chip surface. In a subsequent wet cleaning process, the chemical liquid of the wet cleaning process often has desired electrical conductivity. Therefore, the chemical liquid of the wet cleaning process easily reacts with the charges on the chip surface, and the charges tend to be released rapidly, which causes serious arc defects and causes great damage to the structure of the chip surface, thereby affecting the yield of chips.

At present, deionized water containing carbon dioxide dissolved therein (DICO2) and with a substantially small electrical conductivity is often used to slowly release the charges on the back and front surfaces of the chip. After the surface charges are fully released, a wet cleaning treatment is performed on the chip surface to reduce the discharge degree, thereby preventing the formation of arc defects.

However, the concentration of DICO2 in the entire factory is often fixed, in other words, the electrical conductivity of DICO2 cannot be adjusted as needed. At the same time, in the chip manufacturing process, the amount of charges on the surface of each layer may be different. In the manufacturing process where the amount of charges on some front layers are substantially large, the method of using the deionized water containing carbon dioxide dissolved therein (DICO2) and with a substantially small electrical conductivity to slowly release the charges on the back and front surfaces of the chip has little effect, and a large number of arc defects may still be generated, which may affect the yield of chips.

To solve the above-mentioned problems, the present disclosure provides a cleaning method of a semiconductor structure. The method may include forming a fluid passivation film on the substrate before performing a first charge removal treatment on the substrate surface. On the one hand, when subsequently performing the first charge removal treatment on the substrate surface, in an initial state, the liquid passivation film, the substrate, and a liquid film of the solution of the first charge removal treatment may form a capacitor structure. Therefore, the liquid film of the solution of the first charge removal treatment may not be in direct contact and may not react with the charges on the substrate surface, to avoid generating discharge. On the other hand, as time goes by, the fluid passivation film and the liquid film of the solution of the first charge removal treatment may be inter-soluble, such that the fluid passivation film may dilute the concentration of the liquid film of the solution of the wet cleaning process. Therefore, the conductivity of the formed mixed solution may be reduced, which may effectively prevent the rapid release of the charges on the substrate surface, and may make the release of charges be substantially slow and safe, such that the arc defects may be less likely to occur.

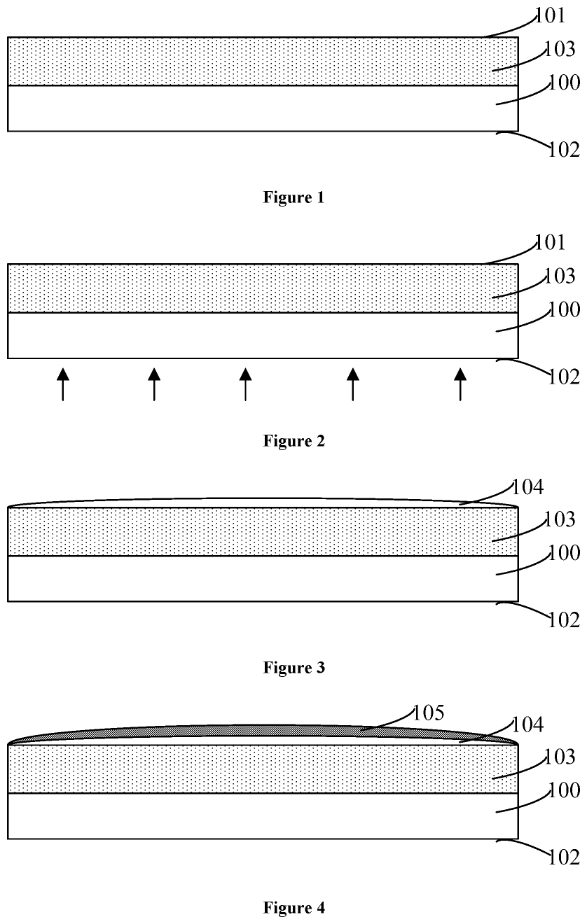

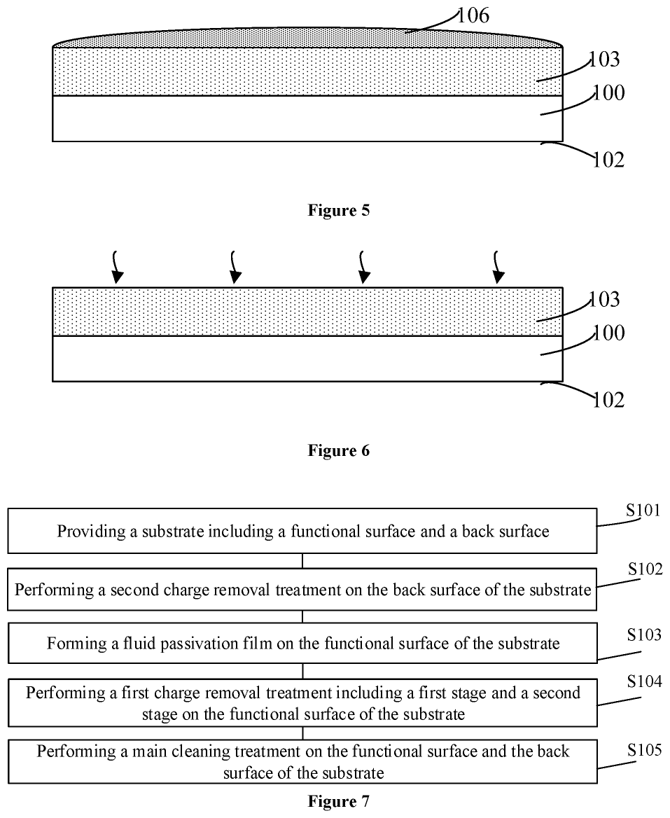

FIG. 7 illustrates a schematic flowchart of a cleaning method of a semiconductor structure consistent with various disclosed embodiments of the present disclosure, and FIGS. 1-6 illustrate schematic diagrams of processes corresponding to certain stages of the cleaning method.

As shown in FIG. 7, at the beginning of the cleaning method, a substrate including a functional surface and a back surface may be provided (S101). FIG. 1 illustrates a corresponding semiconductor structure.

Referring to FIG. 1, a substrate may be provided. The substrate may include a functional surface 101 and a back surface 102 opposite to the functional surface 101. In one embodiment, the substrate may include a base 100, and a device layer 103 over the base. A surface of the device layer 103 may be the functional surface 101 of the substrate. The device layer 103 may include an isolation structure (not illustrated) and a device structure (not illustrated) located in the isolation structure. The device structure may include a transistor, a diode, a triode, a capacitor, an inductor, or a conductive structure.

In one embodiment, the base 100 may be made of silicon. In another embodiment, the base may be made of a material including silicon carbide, silicon germanium, a multicomponent semiconductor material composed of group III-V elements, silicon on insulator (SOI), or germanium on insulator (GOI). The multicomponent semiconductor material composed of group III-V elements may include InP, GaAs, GaP, InAs, InSb, InGaAs or InGaAsP.

In another embodiment, the substrate may further include a dielectric layer located over the device layer, and a conductive layer located in the dielectric layer. The conductive layer may be electrically connected to the device structure, and the surface of the conductive layer may be the functional surface of the substrate.

In certain embodiments, the substrate may include a base and a fin structure over the base. The surface of the fin structure may be the functional surface of the substrate.

Returning to FIG. 7, after providing the substrate, a second charge removal treatment may be performed on the back surface of the substrate (S102). FIG. 2 illustrates a corresponding semiconductor structure.

Referring to FIG. 2, a second charge removal treatment may be performed on the back surface 102 of the substrate. In one embodiment, the second charge removal treatment performed on the substrate surface may include a wet cleaning process. A solution of the wet cleaning process may include a deionized aqueous solution containing carbon dioxide dissolved therein or a deionized aqueous solution containing ammonia dissolved therein.

A conductivity of the deionized aqueous solution containing carbon dioxide dissolved therein (DICO2) or the deionized aqueous solution containing ammonia dissolved therein may be substantially small, such that the surface charges on the back surface 102 of the substrate may be slowly released. After the surface charges are fully released, when subsequently performing a main cleaning treatment on the back surface 102 of the substrate, the charges on the substrate surface may be effectively prevented from being released rapidly, such that the release of charges may be substantially slow and safe, and the arc defects may be less likely to occur.

In certain embodiments, the second charge removal treatment may not be performed on the back surface of the substrate.

Returning to FIG. 7, after performing the second charge removal treatment, a fluid passivation film may be formed on the functional surface of the substrate (S103). FIG. 3 illustrates a corresponding semiconductor structure.

Referring to FIG. 3, a fluid passivation film 104 may be formed on the functional surface 101 of the substrate. The fluid passivation film 104 may be made of a material including liquid, and the liquid may include pure water or isopropanol. In one embodiment, a thickness of the fluid passivation film 104 may be in a range of approximately 0-5 mm.

In one embodiment, the fluid passivation film 104 may be made of a material including pure water. The pure water may not be conductive, such that the fluid passivation film 104 may insulate the functional surface 101 of the substrate. Therefore, when subsequently performing a first charge removal treatment on the substrate surface, in an initial state, the liquid passivation film 104, the substrate, and a liquid film of a solution of the first charge removal treatment may form a capacitor structure, such that the liquid film of the solution of the first charge removal treatment may not be in direct contact and may not react with the charges on the substrate surface, to avoid generating discharge.

Forming the fluid passivation film 104 may include a spray process. Process parameters of the spray process may include a rotation speed in a range of approximately 0-1200 rpm, a flow rate in a range of approximately 0-2000 sccm, and a time period in a range of approximately 0-5 minutes.

After the fluid passivation film 104 is formed, the first charge removal treatment may be performed on the functional surface 101 of the substrate using the wet cleaning process. The process of performing the first charge removal treatment on the functional surface 101 of the substrate may refer to FIG. 4 and FIG. 5.

The wet cleaning process may include a first stage, and a second stage after the first stage.

Returning to FIG. 7, after forming the fluid passivation film, a first charge removal treatment including a first stage and a second stage may be performed on the functional surface of the substrate (S104). FIGS. 4-5 illustrate corresponding semiconductor structures.

Referring to FIG. 4, in the first stage, the liquid film 105 of the solution of the wet cleaning process may cover the surface of the fluid passivation film 104.

In one embodiment, the solution of the wet cleaning process may include the deionized aqueous solution containing carbon dioxide dissolved therein. Parameters of the wet cleaning process may include: a PH value of the solution in a range of approximately 4-7, a conductivity of the solution in a range of approximately 0-50 μS/cm, a flow rate of the solution in a range of approximately 0-2000 sccm, a time period in a range of approximately 0-5 minutes, and a rotation speed in a range of approximately 0-1200 rpm.

The deionized aqueous solution containing carbon dioxide dissolved therein may be conductive, such that the liquid passivation film 104, the substrate and the liquid film 105 of the solution of the wet cleaning process may form a capacitor structure, and the liquid film of the solution of the first charge removal treatment may not be in direct contact and may not react with the charges on the substrate surface, to avoid generating discharge.

In one embodiment, a ratio of the thickness of the fluid passivation film 104 over a thickness of the liquid film 105 may be in a range of approximately 0-5:1. The thickness of the liquid film 105 may be in a range of approximately 0-5 mm.

The above process parameters of the wet cleaning process may make the ratio of the thickness of the formed fluid passivation film 104 over the thickness of the liquid film 105 be in a range of approximately 0-5:1, to ensure that the conductivity of a mixed solution film subsequently formed by diluting the liquid film 105 with pure water decreases. Therefore, the charges on the substrate surface may be effectively prevented from being released rapidly, the release of charges may be substantially slow and safe, and the arc defects may be less likely to occur.

In certain embodiments, the solution of the wet cleaning process may include a deionized aqueous solution containing ammonia dissolved therein. Parameters of the wet cleaning process may include: a PH value of the solution in a range of approximately 7-11, a conductivity of the solution in a range of approximately 0-50 μS/cm, a flow rate of the solution in a range of approximately 0-2000 sccm, a time period in a range of approximately 0-5 minutes, and a rotation speed in a range of approximately 0-1200 rpm.

Referring to FIG. 5, in the second stage, the liquid film 105 of the solution of the wet cleaning process and the fluid passivation film 104 may be inter-soluble, to form a mixed solution film 106. The mixed solution film 106 may be located on the functional surface 101 of the substrate.

In one embodiment, the mixed solution film 106 may include a deionized aqueous solution containing carbon dioxide dissolved therein. A solution of the mixed solution film may have a PH value in a range of approximately 4-7, and may have a conductivity in a range of approximately 0-40 μS/cm.

As time goes by, the fluid passivation film 104 and the liquid film 105 of the solution of the wet cleaning process may be inter-soluble, such that the fluid passivation film 104 may dilute the concentration of the liquid film 105 of the solution of the wet cleaning process, and the mixed solution film 106 may have a conductivity smaller than the liquid film 105 of the solution of the wet cleaning process. The conductivity of the mixed solution film 106 may be substantially low, which may effectively prevent the rapid release of the charges on the substrate surface, and may make the release of charges be substantially slow and safe, such that the arc defects may be less likely to occur.

In certain embodiments, the mixed solution film may be made of a material including a deionized aqueous solution containing ammonia dissolved therein. A solution of the mixed solution film may have a PH value in a range of approximately 7-11, and may have a conductivity in a range of approximately 0-40 μS/cm.

Returning to FIG. 7, after performing the first charge removal treatment, a main cleaning treatment may be performed on the functional surface and the back surface of the substrate (S105). FIG. 6 illustrates a corresponding semiconductor structure.

Referring to FIG. 6, after performing the first charge removal treatment, a main cleaning treatment may be performed on the substrate surface. Because the surface charges on the back surface and the functional surface of the substrate are first slowly released through the deionized water containing carbon dioxide dissolved therein (DICO2) and with a substantially small electrical conductivity, the surface charges may be fully released. Then, when the main cleaning treatment is performed on the back surface and the functional surface of the substrate, the degree of discharge between the solution of the main cleaning treatment and the substrate surface may be reduced, which may prevent the formation of arc defects.

The solution of the main cleaning treatment performed on the substrate surface may include an acidic solution or an alkaline solution. The acidic solution and the alkaline solution may be common cleaning solutions in the technical field, which may be selected according to practical applications, and may not be repeated herein.

The disclosed embodiments may have following beneficial effects. In the disclosed cleaning method of the semiconductor structure, the fluid passivation film may be first formed on the substrate before performing the first charge removal treatment on the substrate surface. On the one hand, when subsequently performing the first charge removal treatment on the substrate surface, in an initial state, the liquid passivation film, the substrate, and the liquid film of the solution of the first charge removal treatment may form the capacitor structure. Therefore, the liquid film of the solution of the first charge removal treatment may not be in direct contact and may not react with the charges on the substrate surface, to avoid generating discharge. On the other hand, as time goes by, the fluid passivation film and the liquid film of the solution of the first charge removal treatment may be inter-soluble, such that the fluid passivation film may dilute the concentration of the liquid film of the solution of the wet cleaning process. Therefore, the conductivity of the formed mixed solution may be reduced, which may effectively prevent the rapid release of the charges on the substrate surface, and may make the release of charges be substantially slow and safe, such that the arc defects may be less likely to occur.

The above detailed descriptions only illustrate certain exemplary embodiments of the present disclosure, and are not intended to limit the scope of the present disclosure. Those skilled in the art can understand the specification as whole and technical features in the various embodiments can be combined into other embodiments understandable to those persons of ordinary skill in the art. Any equivalent or modification thereof, without departing from the spirit and principle of the present disclosure, falls within the true scope of the present disclosure.

What is claimed is:

1. A cleaning method of a semiconductor structure, comprising:
providing a substrate, wherein the substrate comprises a functional surface and a back surface that is opposite to the functional surface;
forming a fluid passivation film on the functional surface of the substrate;
after forming the fluid passivation film, performing a first charge removal treatment on the functional surface of the substrate through a wet cleaning process; and
after performing the first charge removal treatment, performing a main cleaning treatment on the functional surface and the back surface of the substrate.

2. The cleaning method according to claim 1, wherein:
the fluid passivation film is made of a material comprising liquid, wherein the liquid comprises pure water or isopropanol.

3. The cleaning method according to claim 2, wherein:
forming the fluid passivation film comprises a spray process, wherein process parameters of the spray process comprise: a rotation speed in a range of approximately 0-1200 rpm, a flow rate in a range of approximately 0-2000 sccm, and a time period in a range of approximately 0-5 minutes.

4. The cleaning method according to claim 1, wherein:
the wet cleaning process comprises a first stage, and a second stage after the first stage,
in the first stage, a liquid film of a solution of the wet cleaning process covers a surface of the fluid passivation film, and
in the second stage, the liquid film of the solution of the wet cleaning process and the fluid passivation film are inter-soluble, to form a mixed solution film, wherein the mixed solution film is located on the functional surface of the substrate.

5. The cleaning method according to claim 4, wherein:
a ratio of a thickness of the fluid passivation film over a thickness of the liquid film is in a range of approximately 0-5:1.

6. The cleaning method according to claim 5, wherein:
the thickness of the fluid passivation film is in a range of approximately 0-5 mm.

7. The cleaning method according to claim 5, wherein:
the thickness of the liquid film is in a range of approximately 0-5 mm.

8. The cleaning method according to claim 4, wherein:
the solution of the wet cleaning process comprises a deionized aqueous solution containing carbon dioxide dissolved therein, wherein parameters of the wet cleaning process comprise:
a PH value of the solution in a range of approximately 4-7,
an electrical conductivity of the solution in a range of approximately 0-50 μS/cm,
a flow rate of the solution in a range of approximately 0-2000 sccm,
a time period in a range of approximately 0-5 minutes, and
a rotation speed in a range of approximately 0-1200 rpm.

9. The cleaning method according to claim 4, wherein:
the mixed solution film comprises a deionized aqueous solution containing carbon dioxide dissolved therein, wherein a solution of the mixed solution film has a PH value in a range of approximately 4-7, and an electrical conductivity in a range of approximately 0-40 μS/cm.

10. The cleaning method according to claim 4, wherein:
the solution of the wet cleaning process comprises a deionized aqueous solution containing ammonia dissolved therein, wherein parameters of the wet cleaning process comprise:
a PH value of the solution in a range of approximately 7-11,
an electrical conductivity of the solution in a range of approximately 0-50 μS/cm,
a flow rate of the solution in a range of approximately 0-2000 sccm,
a time period in a range of approximately 0-5 minutes, and
a rotation speed in a range of approximately 0-1200 rpm.

11. The cleaning method according to claim 4, wherein:
the mixed solution film comprises a deionized aqueous solution containing ammonia dissolved therein, wherein a solution of the mixed solution film has a PH value in a range of approximately 7-11, and an electrical conductivity in a range of approximately 0-40 μS/cm.

12. The cleaning method according to claim 1, wherein:
a solution of the main cleaning treatment performed on the functional surface and the back surface of the substrate comprises an acidic solution or an alkaline solution.

13. The cleaning method according to claim 1, wherein:
the substrate comprises a base and a fin structure over the base, wherein a surface of the fin structure is the functional surface of the substrate.

14. The cleaning method according to claim 1, wherein:
the substrate comprises a base, and a device layer over the base, wherein:
a surface of the device layer is the functional surface of the substrate,
the device layer comprises an isolation structure and a device structure located in the isolation structure, and
the device structure comprises at least one of a transistor, a diode, a triode, a capacitor, an inductor, and a conductive structure.

15. The cleaning method according to claim 14, wherein:
the substrate further comprises a dielectric layer located over the device layer, and a conductive layer located in the dielectric layer, wherein the conductive layer is electrically connected to the device structure, and a surface of the conductive layer is the functional surface of the substrate.

16. The cleaning method according to claim 1, before forming the fluid passivation film on the functional surface of the substrate, further comprising:
performing a second charge removal treatment on the back surface of the substrate.

17. The cleaning method according to claim 16, wherein:
the second charge removal treatment performed on the back surface of the substrate comprises a wet cleaning process, wherein a solution of the wet cleaning process comprises a deionized aqueous solution containing carbon dioxide dissolved therein or a deionized aqueous solution containing ammonia dissolved therein.
